(19) United States
(12) Patent Application Publication
(10) Pub. No.: US 2025/0370338 A1
(43) Pub. Date: Dec. 4, 2025

(54) NEGATIVE RESIST COMPOSITION AND METHOD FOR PRODUCING RESIST PATTERN

(71) Applicant: Sumitomo Chemical Company, Limited, Tokyo (JP)

(72) Inventors: Suguru TANIGUCHI, Osaka (JP); Masako SUGIHARA, Osaka (JP)

(73) Assignee: Sumitomo Chemical Company, Limited, Tokyo (JP)

(21) Appl. No.: 19/215,029

(22) Filed: May 21, 2025

(30) Foreign Application Priority Data
May 30, 2024 (JP) 2024-087898

(51) Int. Cl. G03F 7/038; G03F 7/004; G03F 7/16; G03F 7/38

(52) U.S. Cl. CPC G03F 7/0382; G03F 7/0045; G03F 7/168; G03F 7/38

(57) ABSTRACT

A negative resist composition and a method for producing a resist pattern using the negative resist composition are described. The negative resist composition includes a resin (A1), an acid generator (B) and a crosslinking agent (E). The resin (A1) includes a structural unit represented by the formula (a2-1) and a structural unit represented by the formula (a2-4); and the acid generator (B) includes at least two acid generators each having a group represented by the formula (B1), and at least one thereof is a compound represented by the formula (b1):

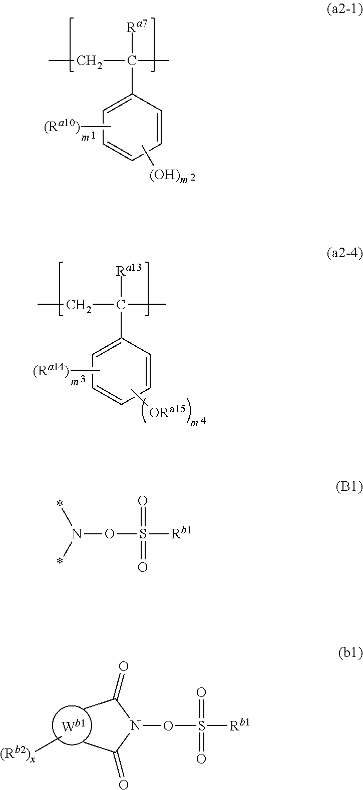

### TECHNICAL FIELD

The present invention relates to a negative resist composition, and a method for producing a resist pattern.

### BACKGROUND ART

Patent Literature 1 discloses a negative resist composition containing a partially ethyl etherified polyvinyl phenol and an m-cresol novolac resin.

### CITATION LIST

### Patent Literature

Patent Literature 1: Japanese Patent Laid-Open No. 2001-42529

### SUMMARY OF INVENTION

### Technical Problem

There are cases where negative resist compositions as disclosed in Patent Literature 1 are not sufficient in the long-term (for example, one month) storage stability.

Then, an object of the present invention is to provide a negative resist composition capable of forming a resist pattern good in storage stability. Furthermore, also an object thereof is to provide a method for producing a resist pattern using the negative resist composition.

### Solution to Problem

As a result of exhaustive studies to solve the above problem, the present inventor has found that the above problem can be solved by making a negative resist composition comprising a resin (A1), an acid generator (B) and a crosslinking agent (E), wherein the resin (A1) has predetermined structural units, and the acid generator (B) comprises two or more acid generators having predetermined groups (chemical structures) and at least one thereof is a compound represented by the formula (b1). Further studies have led to the completion of the present invention.

That is, the present invention relates to the following negative resist composition and method for producing the negative resist composition.

[1] A negative resist composition comprising a resin (A1), an acid generator (B) and a crosslinking agent (E),
wherein the resin (A1) comprises a structural unit represented by the formula (a2-1) and a structural unit represented by the formula (a2-4); and
the acid generator (B) comprises at least two acid generators each having a group represented by the formula (B1), and at least one thereof is a compound represented by the formula (b1):

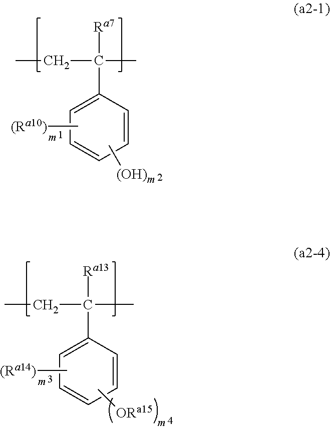

in the formula (a2-1) and the formula (a2-4),
R^{a7} and R^{a13} each independently denote a hydrogen atom or a methyl group;
R^{a10} and R^{a14} each independently denote an alkyl group having 1 to 6 carbon atoms;
R^{a15} denotes a hydrocarbon group having 1 to 12 carbon atoms;
m¹ denotes an integer of 0 to 4, and when m¹ is 2 or more, the plurality of R^{a10} may be identical with or different from each other;
m² denotes an integer of 1 to 4;
provided the total of m¹ and m² is 5 or less;
m³ denotes an integer of 0 to 4, and when m³ is 2 or more, the plurality of R^{a14} may be identical with or different from each other;

m⁴ denotes an integer of 1 to 4, and when m⁴ is 2 or more, the plurality of R^{a15} may be identical with or different from each other; and
provided the total of m³ and m⁴ is 5 or less;

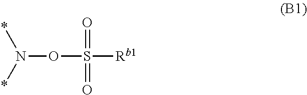

in the formula (B1),
R^{b1} denotes a hydrocarbon group having 1 to 18 carbon atoms and optionally having a fluorine atom; and
a methylene group contained in the hydrocarbon group is optionally substituted by an oxygen atom or a carbonyl group; and

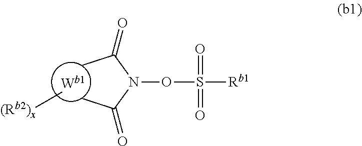

in the formula (b1),
R^{b1} denotes the same meaning as described above;
R^{b2} denotes a hydrocarbon group having 1 to 8 carbon atoms, an alkoxy group having 1 to 8 carbon atoms or a thioalkyl group having 1 to 8 carbon atoms;
the ring W^{b1} denotes an aromatic hydrocarbon ring having 6 to 14 carbon atoms or an aromatic hetero ring having 6 to 14 carbon atoms; and
x denotes an integer of 0 to 6, and in the case where x is 2 or more, the plurality of R^{b2} may be identical or different.

[2] The negative resist composition according to [1],
wherein the acid generator (B) comprises
(i) a combination of at least two selected from compounds represented by the formula (b1); or
(ii) a combination of at least one selected from compounds represented by the formula (b1) with at least one selected from compounds represented by the formula (b2) and compounds represented by the formula (b3):

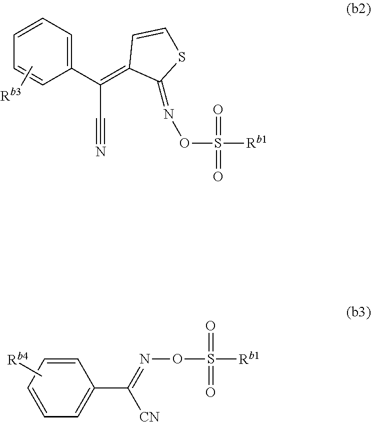

in the formula (b2) and the formula (b3),
R^{b1} denotes the same meaning as described above; and
R^{b3} and R^{b4} each independently denote a hydrogen atom, a hydrocarbon group having 1 to 8 carbon atoms, an alkoxy group having 1 to 8 carbon atoms or a thioalkyl group having 1 to 8 carbon atoms.

[3] The negative resist composition according to [1] or [2], wherein at least one contained in the acid generator (B), selected from compounds represented by the formula (b1) is a compound wherein x is 1.

[4] The negative resist composition according to any one of [1] to [3], further comprising a novolac resin.

[5] The negative resist composition according to any one of [1] to [4], further comprising a quencher (C).

[6] The negative resist composition according to any one of [1] to [5], wherein the crosslinking agent (E) is a melamine-based crosslinking agent or a glycoluril-based crosslinking agent.

[7] A method for producing a resist pattern, comprising:
(1) a step of coating a substrate with a resist composition according to any one of [1] to [6];
(2) a step of drying the composition after the coating to form a composition layer;
(3) a step of exposing the composition layer; and
(4) a step of heating and developing the composition layer after the exposure.

### Advantageous Effects of Invention

According to the present invention, a negative resist composition good in the storage stability can be obtained.

### BRIEF DESCRIPTION OF DRAWING

FIG. 1 is a schematic diagram showing trench pattern shapes of a resist pattern.

### DESCRIPTION OF EMBODIMENTS

In the present description, the “hydrocarbon group” in the description of structural formulae of compounds means, unless otherwise specified, a straight-chain or branched-chain acyclic hydrocarbon group, an alicyclic hydrocarbon group, an aromatic hydrocarbon group and a group in a combination of these groups. In the case where the number of carbon atoms of the “hydrocarbon group” is specified, the “hydrocarbon group” can be an above-mentioned group in the specified range of the number of carbon atoms. In the case where stereoisomers exist, the “hydrocarbon group” includes every stereoisomer.

In the present description, “(meth)acrylic acid” means “at least one of acrylic acid and methacrylic acid”, and a “(meth)acrylate” means “at least one of an acrylate and a methacrylate”.

With regard to groups described in the present description, groups which can have both of a straight-chain structure and a branched-chain structure are interpreted to include either thereof.

In the present description, a “solid content of a negative resist composition” means the total of components excluding a solvent (D) to be described later from the total amount of the negative resist composition.

### 1. Negative Resist Composition

The negative resist composition of the present invention comprises a resin (hereinafter, referred to as a “resin (A1)” in some cases) having a structural unit (hereinafter, referred to as a structural unit (a2-1) in some cases) represented by the formula (a2-1) and a structural unit (hereinafter, referred to as a structural unit (a2-4) in some cases) represented by the formula (a2-4), a crosslinking agent (hereinafter, referred to as a “crosslinking agent (E)” in some cases) and an acid generator (hereinafter, referred to as an “acid generator (B)” in some cases).

The negative resist composition of the present invention, as required, may further comprise a novolac resin (hereinafter, referred to as a “novolac resin (A2)” in some cases), a quencher (hereinafter, referred to as a quencher (C) in some cases), a solvent (hereinafter, referred to as a “solvent (D)” in some cases), and other components (hereinafter, referred to as “other components (F)” in some cases).

The negative resist composition of the present invention comprises the resin (A1), and may further comprise an alkali-soluble resin. The alkali-soluble resin is a resin having an acidic group (referred to as a hydrophilic group in some cases) and being soluble to an alkali developing solution. The acidic group is, for example, a carboxy group, a sulfo group, or a hydroxy group (phenolic hydroxy group or the like).

The alkali-soluble resin includes alkali-soluble resins well known in the resist field, and includes, for example, novolac resins (A2), resins having a structural unit (a2-1) and no structural unit (a2-4), resins having a structural unit originated from a (meth)acrylate ester, and polyalkylene glycols.

### <Resin (A1)>

The resin (A1) is a resin having a structural unit (a2-1) and a structural unit (a2-4), and is an alkali-soluble resin.

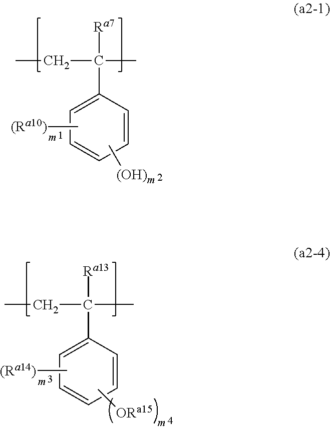

In the formula (a2-1) and the formula (a2-4),
R^{a7} and R^{a13} each independently denote a hydrogen atom or a methyl group;
R^{a10} and R^{a14} each independently denote an alkyl group having 1 to 6 carbon atoms;
R^{a15} denotes a hydrocarbon group having 1 to 12 carbon atoms;
m¹ denotes an integer of 0 to 4, and when m¹ is 2 or more, the plurality of R^{a10} may be identical with or different from each other;
m² denotes an integer of 1 to 4;
provided the total of m¹ and m² is 5 or less;
m³ denotes an integer of 0 to 4, and when m³ is 2 or more, the plurality of R^{a14} may be identical with or different from each other;
m⁴ denotes an integer of 1 to 4, and when m⁴ is 2 or more, the plurality of R^{a15} may be identical with or different from each other; and
provided the total of m³ and m⁴ is 5 or less.

The hydrocarbon group having 1 to 12 carbon atoms denoted by R^{a15} includes straight-chain or branched-chain acyclic hydrocarbon groups having 1 to 12 carbon atoms (particularly, alkyl groups having 1 to 12 carbon atoms, alkenyl groups having 2 to 12 carbon atoms and alkynyl groups having 2 to 12 carbon atoms, and the like), alicyclic hydrocarbon groups having 3 to 12 carbon atoms, aromatic hydrocarbon groups having 6 to 12 carbon atoms, and groups having 4 to 12 carbon atoms in combinations of these groups. Among these, groups in which a carbon atom bound to an oxygen atom is a tertiary carbon atom are excluded. A methylene group contained in the hydrocarbon group having 1 to 12 carbon atoms is optionally substituted by an oxygen atom or a carbonyl group. Provided a methylene group bound to an oxygen atom and a methylene group bound to the methylene group are not substituted by an oxygen atom.

R^{a15} is preferably an alkyl group having 1 to 6 carbon atoms, more preferably an alkyl group having 1 to 4 carbon atoms, and still more preferably a methyl group, an ethyl group and a propyl group.

In the resin (A1), the content rate of the structural unit (a2-1) is, with respect to all the structural units of the resin (A1), preferably 10 to 90% by mol and more preferably 20 to 85% by mol.

In the resin (A1), the content rate of the structural unit (a2-4) is, with respect to all the structural units of the resin (A1), preferably 3 to 40% by mol, more preferably 5 to 30% by mol and still more preferably 10 to 25% by mol.

The resin (A1) may comprise structural units other than the structural unit (a2-1) and the structural unit (a2-4). Such structural units include structural units of monomers in which a hydroxy group of hydroxystyrene is substituted by another group, and structural units of monomers having an α,β-unsaturated double bond.

Then, monomers forming such structural units include styrene-based monomers such as styrene, chlorostyrene and α-methylstyrene, acrylic monomers such as acrylic acid, methacrylic acid, methyl acrylate and methyl methacrylate, and vinyl acetate-based monomers such as vinyl acetate and vinyl benzoate.

The resin (A1) can be produced, for example, by a method disclosed in Japanese Patent Laid-Open No. 7-295220.

The weight-average molecular weight of the resin (A1) is preferably 1,000 or higher, more preferably 1,500 or higher and still more preferably 2,000 or higher, and preferably 10,000 or lower, more preferably 8,000 or lower and still more preferably 5,000 or lower. The weight-average molecular weight is determined by gel permeation chromatography in terms of standard polystyrenes. The detailed analysis condition thereof will be described in Examples in the present application.

### <Novolac Resin (A2)>

The novolac resin (A2) is a resin obtained by condensing a phenol compound and aldehyde in the presence of a catalyst, and is, for example, a resin comprising a structural unit represented by the following formula (a4).

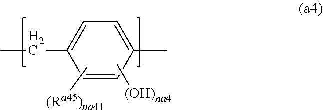

In the formula (a4),
R^{a45} denotes a halogen atom, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, and an acryloyl group or a methacryloyloxy group;
na4 denotes an integer of 1 to 4;
na41 denotes an integer of 0 to 3, and when na41 is 2 or more, the plurality of R^{a45} may be identical with or different from each other; and
provided 1≤na4+na41≤4.

In the formula (a4), the halogen atom of R^{a45} includes a fluorine atom, a chlorine atom, a bromine atom and an iodine atom.

The alkyl group having 1 to 6 carbon atoms of R^{a45} may be a straight-chain or branched-chain alkyl group, and includes, for example, a methyl group, an ethyl group, a propyl group, a butyl group, a pentyl group and a hexyl group.

The haloalkyl group having 1 to 6 carbon atoms of R^{a45} includes groups in which a hydrogen atom contained in the above alkyl group is substituted by the above halogen atom, and includes alkyl fluoride groups having 1 to 6 carbon atoms, alkyl chloride groups having 1 to 6 carbon atoms, alkyl bromide groups having 1 to 6 carbon atoms, or alkyl iodide groups having 1 to 6 carbon atoms; and among these, a perfluoroalkyl group having 1 to 3 carbon atoms is preferable.

The alkoxy group having 1 to 6 carbon atoms of R^{a45} includes a methoxy group, an ethoxy group, a propoxy group, an isopropoxy group, a butoxy group, a sec-butoxy group, and a tert-butoxy group. The number of carbon atoms of the alkoxy group is preferably 1 to 4 and more preferably 1 to 3; and still more preferable is a methoxy group or an ethoxy group, and further still more preferable is a methoxy group.

The alkoxyalkyl group having 2 to 12 carbon atoms of R^{a45} includes a methoxymethyl group, an ethoxyethyl group, a propoxymethyl group, an isopropoxymethyl group, a butoxymethyl group, a sec-butoxymethyl group and a tert-butoxymethyl group. The alkoxyalkyl group is preferably an alkoxyalkyl group having 2 to 8 carbon atoms, more preferably a methoxymethyl group or an ethoxyethyl group, and still more preferably a methoxymethyl group.

The alkoxyalkoxy group having 2 to 12 carbon atoms of R^{a45} includes a methoxymethoxy group, a methoxyethoxy group, an ethoxymethoxy group, an ethoxyethoxy group, a propoxymethoxy group, an isopropoxymethoxy group, a butoxymethoxy group, a sec-butoxymethoxy group and a tert-butoxymethoxy group. The alkoxyalkoxy group is preferably an alkoxyalkoxy group having 2 to 8 carbon atoms, and more preferably a methoxyethoxy group or an ethoxyethoxy group.

The alkylcarbonyl group having 2 to 4 carbon atoms of R^{a45} includes an acetyl group, a propionyl group and a butyryl group. The alkylcarbonyl group is preferably an alkylcarbonyl group having 2 or 3 carbon atoms, and more preferably an acetyl group.

The alkylcarbonyloxy group having 2 to 4 carbon atoms of R^{a45} includes an acetyloxy group, a propionyloxy group and a butyryloxy group. The alkylcarbonyloxy group is preferably an alkylcarbonyloxy group having 2 or 3 carbon atoms, and more preferably an acetyloxy group.

In the formula (a4), R^{a45} is preferably an alkyl group having 1 to 4 carbon atoms or an alkoxy group having 1 to 4 carbon atoms, more preferably an alkyl group having 1 to 3 carbon atoms or an alkoxy group having 1 to 3 carbon atoms, still more preferably a methyl group, an ethyl group, a methoxy group or an ethoxy group, and further still more preferably a methyl group or a methoxy group.

na4 is preferably 1 or 2, and more preferably 1.

na41 is preferably 0, 1 or 2, and more preferably 0 or 1.

The weight-average molecular weight of the novolac resin (A2) is preferably 3,000 or higher, more preferably 4,000 or higher, still more preferably 5,000 or higher and further still more preferably 6,000 or higher, and preferably 100,000 or lower, more preferably 50,000 or lower, still more preferably 10,000 or lower, further still more preferably 9,000 or lower and even further still more preferably 8,000 or lower. By making the weight-average molecular weight to be in this range, film thinning and residue remaining after development can effectively be prevented. The weight-average molecular weight is determined by gel permeation chromatography in terms of standard polystyrenes. The detailed analysis condition thereof will be described in Examples in the present application.

The content of the resin (A2) is, with respect to the total amount of resins contained in the negative resist composition, preferably 5% by mass or higher, more preferably 10% by mass or higher and still more preferably 20% by mass or higher, and preferably 90% by mass or lower, more preferably 80% by mass or lower, still more preferably 70% by mass or lower and further still more preferably 65% by mass or lower.

<Resin Having a Structural Unit Originated from a (Meth)Acrylate Ester>

The resin having a structural unit originated from a (meth)acrylate ester includes resins obtained, for example, by using the following compounds as monomers, and polymerizing one or more of the monomers in combination by a usual method. The resin having a structural unit originated from a (meth)acrylate ester includes resins having a structural unit originated from any one of the following monomers:
monomers having a carboxy group, such as (meth)acrylic acid; monomers having a hydroxy group, such as 2-hydroxyethyl (meth)acrylate and 2-hydroxypropyl (meth)acrylate; and monomers having a plurality of ether bonds, including polyethylene glycol monomethyl ether (meth)acrylates (polyalkylene glycol monoalkyl ether (meth)acrylates), such as diethylene glycol monomethyl ether (meth)acrylate, triethylene glycol monomethyl ether (meth)acrylate, tetraethylene glycol monomethyl ether (meth)acrylate, pentaethylene glycol monomethyl ether (meth)acrylate, hexaethylene glycol monomethyl ether (meth)acrylate, heptaethylene glycol monomethyl ether (meth)acrylate, octaethylene glycol monomethyl ether (meth)acrylate, and nonaethylene glycol monomethyl ether (meth)acrylate.

There may be used a combination of any one of the above-mentioned monomers with any one or another of (meth)acrylic acid alkyl esters such as methyl (meth)acrylate, ethyl (meth)acrylate, propyl (meth)acrylate, tert-butyl (meth)acrylate and hexyl (meth)acrylate; monocyclic (meth)acrylic acid esters including (meth)acrylic acid cycloalkyl esters such as cyclopentyl (meth)acrylate and cyclohexyl (meth)acrylate; polycyclic (meth)acrylic acid esters such as adamantyl (meth)acrylate and norbornyl (meth)acrylate; (meth)acrylic acid aryl esters such as phenyl (meth)acrylate and benzyl (meth)acrylate; ethylene glycol monoalkyl ether (meth)acrylates (alkylene glycol monoalkyl ether (meth)acrylates), such as ethylene glycol monomethyl ether (meth)acrylate, ethylene glycol monoethyl ether (meth)acrylate, ethylene glycol monopropyl ether (meth)acrylate and ethylene glycol monobutyl ether (meth)acrylate; and the like. There also may be used a combination of any one of the above monomers with any one or another of styrenes such as styrene, α-methylstyrene, 4-methylstyrene, 2-methylstyrene, 3-methylstyrene, 4-methoxystyrene and 4-isopropoxystyrene; carboxylic acids such as crotonic acid, maleic acid, fumaric acid, citraconic acid, mesaconic acid and itaconic acid; and hydroxystyrenes exemplified in the above-mentioned resins having a structural unit originated from hydroxystyrene. Structural units originated from monomers like the above also include the structural units represented by the formula (a2-1) and the formula (a2-4).

### <Polyalkylene Glycol>

The polyalkylene glycol is a polymer obtained by addition polymerization of any one of alkylene oxides to any one of alcohols. Examples of the alcohols include butanol, ethylene glycol, propylene glycol, glycerol and pentaerythritol. Examples of the alkylene oxides include ethylene oxide, propylene oxide and butylene oxide. The polyalkylene glycol includes polyethylene glycol, polypropylene glycol and polybutylene glycol.

### <Acid Generator (B)>

The acid generator (B) is a compound which can generate an acid by being decomposed by light irradiation (exposure). The acid generated acts as an acid catalyst to promote crosslinking reaction, and can form crosslinks by bonding of a crosslinking agent with reactive groups in a resin. That is, by exposing the negative resist composition containing the resin (A1), the composition can be made to become insoluble to a resist developing solution (alkali aqueous solution).

The acid generator (B) comprises at least two acid generators having a group represented by the formula (B1), and at least one thereof is a compound represented by the formula (b1).

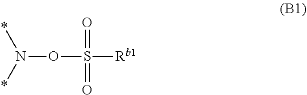

In the formula (B1),
R^{b1} denotes a hydrocarbon group having 1 to 18 carbon atoms and optionally having a fluorine atom(s); a methylene group contained in the hydrocarbon group is optionally substituted by an oxygen atom or a carbonyl group; and * denotes a bond.

The hydrocarbon group having 1 to 18 carbon atoms in the hydrocarbon group, R^{b1}, having 1 to 18 carbon atoms and optionally having a fluorine atom(s) includes straight-chain or branched-chain acyclic hydrocarbon groups having 1 to 18 carbon atoms, alicyclic hydrocarbon groups having 3 to 18 carbon atoms, aromatic hydrocarbon groups having 6 to 18 carbon atoms, and groups having 4 to 18 carbon atoms in combination of these groups.

The straight-chain or branched-chain acyclic hydrocarbon groups having 1 to 18 carbon atoms are preferably alkyl groups having 1 to 18 carbon atoms, and examples thereof include a methyl group, an ethyl group, a propyl group, a butyl group, a pentyl group, a hexyl group, a heptyl group, an octyl group, a nonyl group, and a decyl group. Among these, straight-chain ones are preferable.

Examples of the alicyclic hydrocarbon groups having 3 to 18 carbon atoms include a cyclopropyl group, a cyclobutyl group, a cyclopentyl group, a cyclohexyl group, a cycloheptyl group, a cyclooctyl group, and an adamantyl group.

The aromatic hydrocarbon groups having 6 to 18 carbon atoms are preferably aryl groups having 6 to 18 carbon atoms, and examples thereof include aryl groups, such as a phenyl group, a naphthyl group, an anthryl group, a biphenyl group, and a phenanthryl group.

Among the groups having 4 to 18 carbon atoms in combination of the above groups, examples of groups (having 4 to 18 carbon atoms) in combination of an acyclic hydrocarbon group with an alicyclic hydrocarbon group include a methylcyclohexyl group, a dimethylcyclohexyl group, a methylnorbornyl group, an isobornyl group, 2-alkyladamant-2-yl groups and 1-(adamant-1-yl)alkan-1-yl groups.

Groups (having 7 to 18 carbon atoms) in combination of an acyclic hydrocarbon group with an aromatic hydrocarbon group are, for example, aralkyl groups and aromatic hydrocarbon groups having an alkyl group, and specifically include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, a 2-methyl-6-ethylphenyl group.

Groups (having 9 to 18 carbon atoms) in combination of an alicyclic hydrocarbon group with an aromatic hydrocarbon group are, for example, aromatic hydrocarbon groups having an alicyclic hydrocarbon group, and alicyclic hydrocarbon groups having an aromatic hydrocarbon group, and specifically include a p-cyclohexylphenyl group, a p-adamantylphenyl group and a phenylcyclohexyl group.

Among hydrocarbon groups having 1 to 18 carbon atoms denoted by R^{b1}, preferable are alkyl groups having 1 to 10 carbon atoms and aromatic hydrocarbon groups having 6 to 10 carbon atoms; more preferable are alkyl groups having 1 to 8 carbon atoms; and still more preferable are alkyl groups having 1 to 4 carbon atoms.

Examples of the group in which a methylene group contained in the alicyclic hydrocarbon group having 3 to 18 carbon atoms in R^{b1} is substituted by an oxygen atom or a carbonyl group include groups represented by the formula (Y1) to the formula (Y12). The group is preferably a group represented by the formula (Y7) to the formula (Y9), and more preferably a group represented by the formula (Y9).

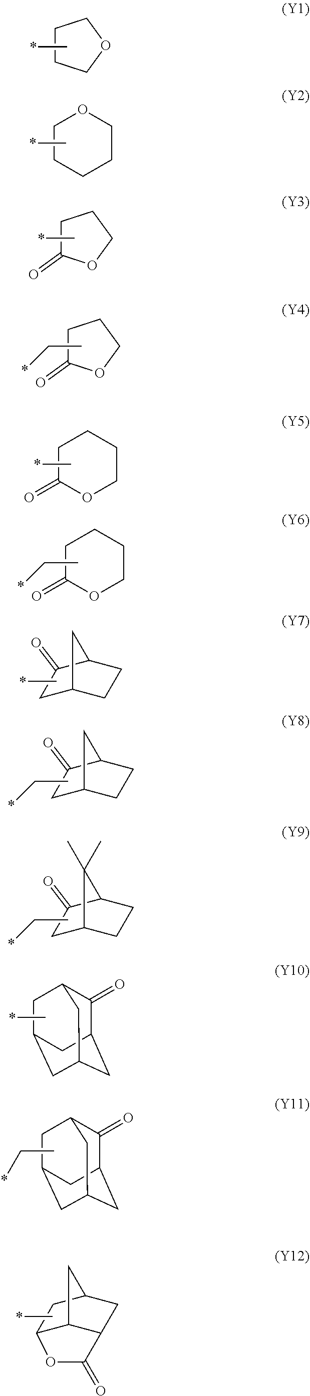

The hydrocarbon group having 1 to 18 carbon atoms and having a fluorine atom(s) is a group in which one or more of hydrogen atoms contained in the above hydrocarbon group having 1 to 18 carbon atoms are substituted by a fluorine atom(s), and specific examples thereof include fluoroalkyl groups, such as a fluoromethyl group, a fluoroethyl group, a fluoropropyl group, a fluorobutyl group, a fluoropentyl group, a fluorohexyl group, a fluoroheptyl group, a fluorooctyl group, a fluorononyl group and a fluorodecyl group; fluorocycloalkyl groups, such as a fluorocyclopropyl group, a fluorocyclobutyl group, a fluorocyclopentyl group, a fluorocyclohexyl group, a fluorocycloheptyl group, a fluorocyclooctyl group and a fluoroadamantyl group; and fluoroaryl groups, such as a fluorophenyl group, a fluoronaphthyl group and a fluoroanthryl group.

The hydrocarbon group having 1 to 18 carbon atoms and having a fluorine atom(s) is preferably an alkyl group having 1 to 10 carbon atoms and having a fluorine atom(s), or an aromatic hydrocarbon group having 6 to 10 carbon atoms and having a fluorine atom(s), more preferably a perfluoroalkyl group having 1 to 8 carbon atoms, and still more preferably a perfluoroalkyl group having 1 to 4 carbon atoms.

Among at least two acid generators having a group represented by the formula (B1), at least one is a compound represented by the formula (b1).

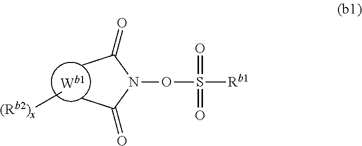

In the formula (b1),
R^{b1} denotes the same meaning as in the above;
R^{b2} denotes a hydrocarbon group having 1 to 8 carbon atoms, an alkoxy group having 1 to 8 carbon atoms or a thioalkyl group having 1 to 8 carbon atoms;
the ring W^{b1} denotes an aromatic hydrocarbon ring having 6 to 14 carbon atoms or an aromatic hetero ring having 6 to 14 carbon atoms; and
x denotes an integer of 0 to 6, and in the case where x is 2 or more, the plurality of R^{b2} may be identical or different.

The hydrocarbon group having 1 to 8 carbon atoms denoted by R^{b2} may be a straight-chain or branched-chain one, and includes alkyl groups having 1 to 8 carbon atoms, alkenyl groups having 1 to 8 carbon atoms and alkynyl groups having 1 to 8 carbon atoms. Preferable are alkyl groups having 1 to 8 carbon atoms; more preferable are alkyl groups having 1 to 6 carbon atoms; and still more preferable are alkyl groups having 1 to 4 carbon atoms.

Examples of the alkyl groups having 1 to 8 carbon atoms include a methyl group, an ethyl group, a propyl group, a butyl group and a pentyl group.

Examples of the alkoxy groups having 1 to 8 carbon atoms denoted by R^{b2} include a methoxy group, an ethoxy group, a propoxy group, a butoxy group and a pentyloxy group.

Examples of the thioalkyl groups having 1 to 8 carbon atoms denoted by R^{b2} include a thiomethyl group, a thioethyl group, a thiopropyl group, a thiobutyl group and a thiopentyl group.

Examples of the aromatic hydrocarbon ring having 6 to 14 carbon atoms denoted by the ring W^{b1} include a benzene ring, a naphthalene ring and an anthracene ring.

Examples of the aromatic hetero ring having 6 to 14 carbon atoms denoted by the ring W^{b1} include rings having 6 to 14 atoms constituting the ring, and preferably include the following rings.

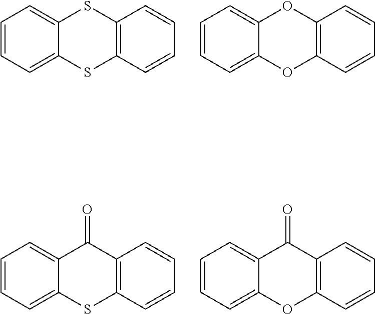

The ring W^{b1} is preferably a naphthalene ring.

The compound represented by the formula (b1) is preferably a compound represented by one of the formula (b4) to the formula (b7), and more preferably a compound represented by the formula (b4).

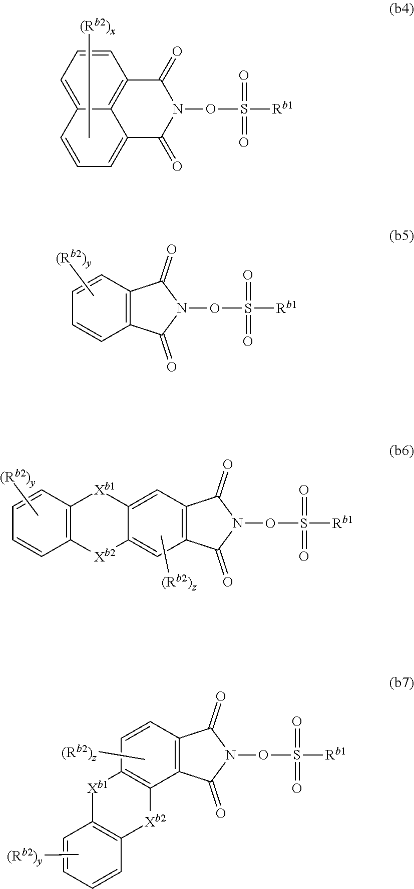

In the formula (b4) to the formula (b7),
R^{b1}, R^{b2} and x denote the same meanings as in the above;
y denotes an integer of 0 to 4, and z denotes an integer of 0 to 2; and
X^{b1} and X^{b2} each independently denote —O—, —S— or —CO—.

Examples of the compound represented by the formula (b1) include compounds represented by the formula (b1-1) to the formula (b1-24). Preferable are compounds represented by the formula (b1-6) to the formula (b1-10), the formula (b1-13) to the formula (b1-15), and the formula (b1-20) to the formula (b1-22).

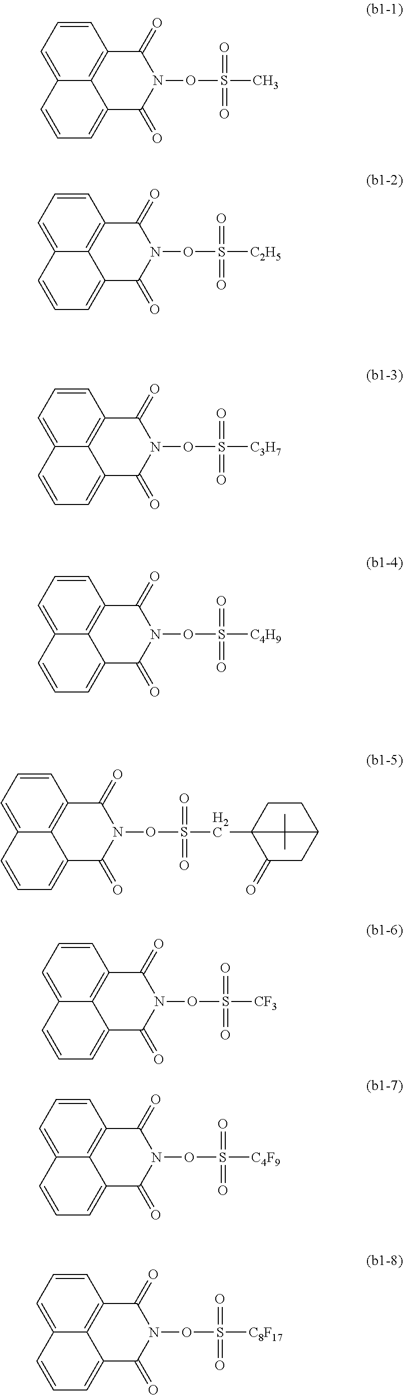

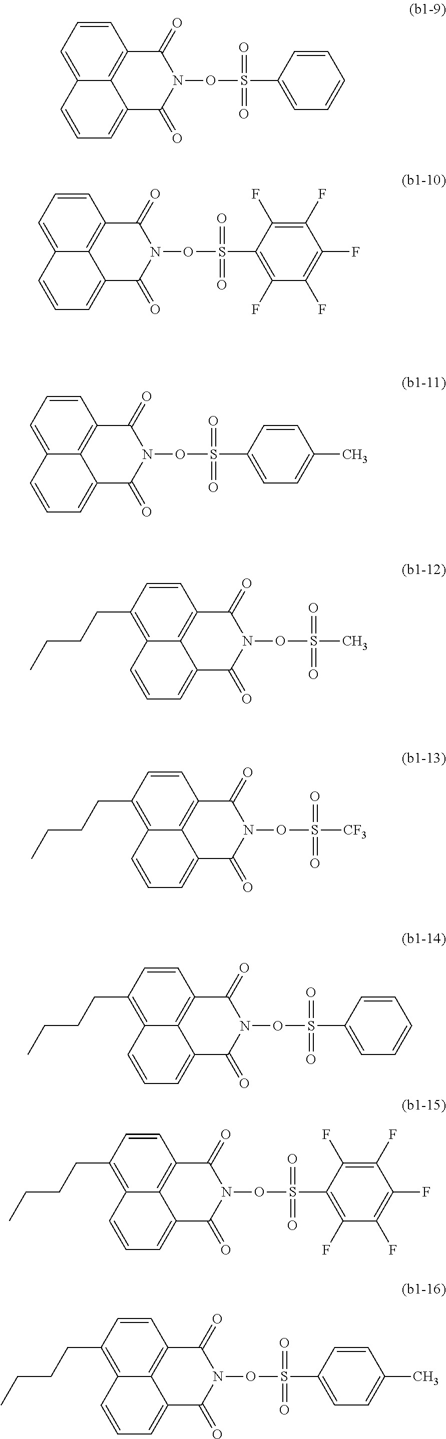

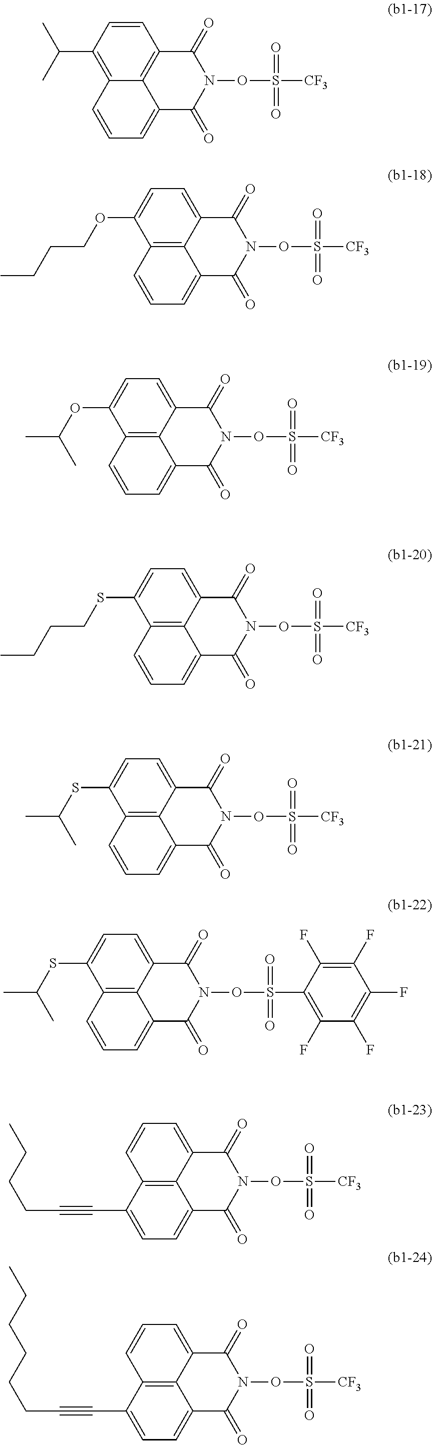

At least two acid generators having a group represented by the formula (B1), included in the acid generator (B), can comprise compounds other than the compound represented by the formula (b1). Examples of the compounds include compounds represented by the formula (b2) and compounds represented by the formula (b3).

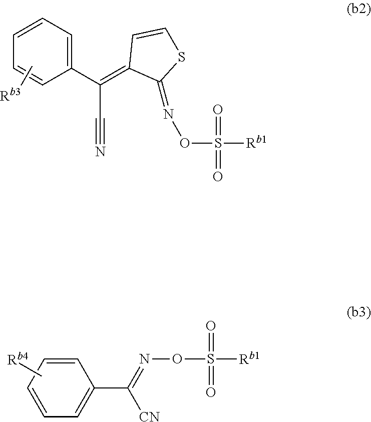

In the formula (b2) and the formula (b3),
R^{b1} denotes the same meaning as in the above; and
R^{b3} and R^{b4} each independently denote a hydrogen atom, a hydrocarbon group having 1 to 8 carbon atoms, an alkoxy group having 1 to 8 carbon atoms, or a thioalkyl group having 1 to 8 carbon atoms.

The hydrocarbon groups having 1 to 8 carbon atoms denoted by R^{b3} and R^{b4} each independently include the same as the hydrocarbon groups having 1 to 8 carbon atoms denoted by R^{b2}.

The alkoxy groups having 1 to 8 carbon atoms denoted by R^{b3} and R^{b4} each independently include the same as the alkoxy groups having 1 to 8 carbon atoms denoted by R^{b2}.

The thioalkyl groups having 1 to 8 carbon atoms denoted by R^{b3} and R^{b4} each independently include the same as the thioalkyl groups having 1 to 8 carbon atoms denoted by R^{b2}.

Examples of the compounds represented by the formula (b2) include compounds represented by the following formulae.

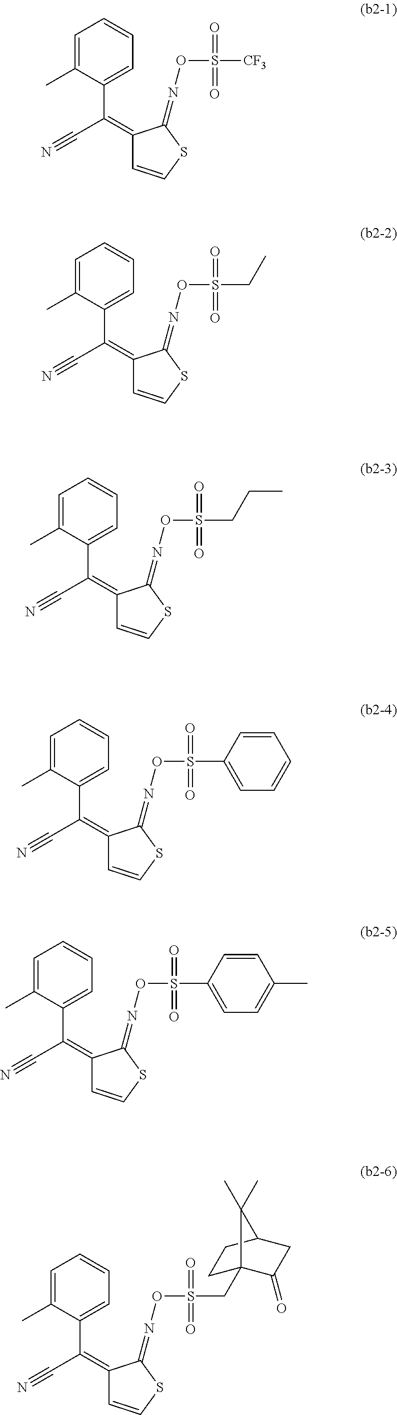

Examples of the compounds represented by the formula (b3) include compounds represented by the following formulae.

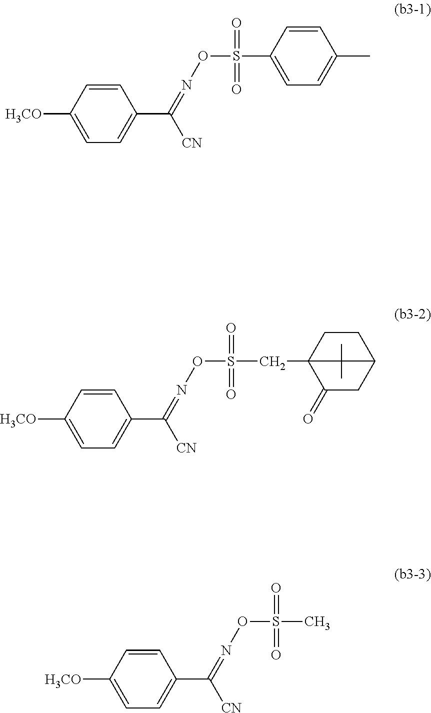 [SMILES: COc1ccc(C(C#N)=NOS(=O)(=O)c2ccc(C)cc2)cc1 ; COc1ccc(C(C#N)=NOS(=O)(=O)CC23CCC(CC2=O)C3(C)C)cc1 ; COc1ccc(C(C#N)=NOS(C)(=O)=O)cc1]

At least one selected from the compounds represented by the formula (b1), contained in the acid generator (B), is preferably compounds in which x is 1. Among these, preferable are the compounds in which R^{b2} is a hydrocarbon group having 1 to 8 carbon atoms, and more preferable are the compounds in which R^{b2} is an alkyl group having 1 to 8 carbon atoms.

Examples of the preferable acid generator (B) include ones comprising the following combinations:
(i) Combinations of at least two selected from the compounds represented by the formula (b1), or
(ii) Combinations of at least one selected from the compounds represented by the formula (b1) with at least one selected from the compounds represented by the formula (b2) and the compounds represented by the formula (b3).

Among the combinations of the above (i), preferable ones include combinations of at least one selected from the compounds represented by the formula (b1) (in the formula, x is 1, and R^{b1}, R^{b2} and W^{b1} denote the same meaning as described above) with at least one selected from the compounds represented by the formula (b1) (in the formula, x is 0, and R^{b1} and W^{b1} denote the same meaning as described above).

Among the combinations of the above (i), other preferable ones include combinations of at least two selected from the compounds represented by from the formula (b4) to the formula (b7).

Among the combinations of the above (i), other preferable ones include combinations of at least two selected from the compounds represented by the formula (b4).

Among the combinations of the above (i), other preferable ones include combinations of at least one selected from the compounds represented by the formula (b4) (in the formula, x is 0, and R^{b1} and R^{b2} denote the same meanings as in the above) with at least one selected from the compounds represented by the formula (b4) (in the formula, x is 1, and R^{b1} and R^{b2} denote the same meanings as in the above).

Among the combinations of the above (i), other preferable ones include combinations of at least one selected by from the formula (b1-1) to the formula (b1-11) with at least one selected by from the formula (b1-12) to the formula (b1-24).

Among the combinations of the above (ii), preferable ones include combinations of at least one selected from the compounds represented by the formula (b4) with at least one selected from the compounds represented by the formula (b2) and the compounds represented by the formula (b3).

Among the combinations of the above (ii), other preferable ones include combinations of at least one selected from the compounds represented by the formula (b4) with at least one selected from the compounds represented by the formula (b2).

Among the combinations of the above (ii), other preferable ones include combinations of at least one selected by from the formula (b1-1) to the formula (b1-24) with at least one selected by from the formula (b2-1) to the formula (b2-6) and from the formula (b3-1) to the formula (b3-3).

Among the combinations of the above (ii), other preferable ones include combinations of at least one selected by from the formula (b1-1) to the formula (b1-24) with at least one selected by from the formula (b2-1) to the formula (b2-6).

Although the acid generator (B) to be used in the present invention essentially contains, as described above, at least two acid generators (at least one thereof is a compound represented by the formula (b1)) having a group represented by the formula (B1), acid generators (nonionic acid generators, ionic acid generators and the like) other than the at least two acid generators may be contained in such a range not to adversely affect the advantageous effects of the present invention.

Examples of the nonionic acid generators include (provided the acid generators essentially contained in the present invention are excluded) organic halides, sulfonate esters (for example, 2-nitrobenzyl ester, aromatic sulfonates, oxime sulfonates, N-sulfonyl oxyimide, sulfonyl oxyketones and diazonaphthoquinone-4-sulfonate) and sulfones (for example, disulfones, ketosulfones and sulfonyldiazomethanes).

Examples of the ionic acid generators typically include onium salts containing onium cations (for example, diazonium salts, phosphonium salts, sulfonium salts and iodonium salts). Anions of the onium salts include sulfonate anions, sulfonylimide anions and sulfonylmethide anions.

As these acid generators, there can be used compounds generating acids by radioactive rays disclosed in Japanese Patent Laid-Open Nos. 63-26653, 55-164824, 62-69263, 63-146038, 63-163452, 62-153853 and 63-146029, U.S. Pat. Nos. 3,779,778 and 3,849,137, German Patent No. 3914407, European Patent No. 126712, and the like. Compounds produced by well-known methods may also be used. The acid generators (B) may be used singly or in combination of two or more.

The ionic acid generator is preferably a compound represented by the formula (b8) or the formula (b9).

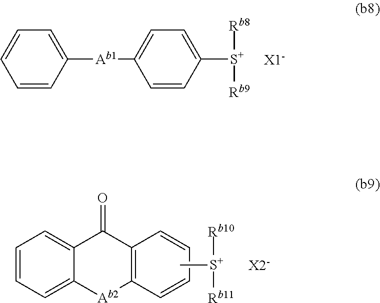

In the formula (b8) and the formula (b9),
A^{b1} and A^{b2} each independently denote an oxygen atom or a sulfur atom;
R^{b8}, R^{b9}, R^{b10} and R^{b11} each independently denote an alkyl group having 1 to 10 carbon atoms or an aromatic hydrocarbon group having 6 to 12 carbon atoms; and
X1⁻ and X2⁻ denote an organic anion.

Examples of the alkyl group having 1 to 10 carbon atoms include a methyl group, an ethyl group, a propyl group, a butyl group, a pentyl group, a hexyl group, a heptyl group and an octyl group.

Examples of the aromatic hydrocarbon group having 6 to 12 carbon atoms include aryl groups such as a phenyl group, a naphthyl group, an anthryl group, a biphenyl group and a phenanthryl group. The aromatic hydrocarbon group optionally further has a substituent, and aromatic hydrocarbon groups having a substituent are, for example, aromatic hydrocarbon groups having an aralkyl group or an alkyl group, and specifically include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group and a 2-methyl-6-ethylphenyl group.

R^{b8}, R^{b9}, R^{b10} and R^{b11} are each preferably an aromatic hydrocarbon group having 6 to 12 carbon atoms, and more preferably a phenyl group.

Examples of the organic anions denoted by X1⁻ and X2⁻ include sulfonate anions, bis(alkylsulfonyl)amide anions and tris(alkylsulfonyl) methide anions; and preferable are sulfonate anions, and more preferably are sulfonate anions represented by the formula (b10).

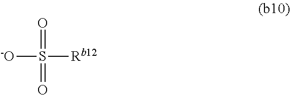

In the formula (b10),
R^{b12} denotes a hydrocarbon group having 1 to 18 carbon atoms and optionally having a fluorine atom(s), and a methylene group contained in the hydrocarbon group is optionally substituted by an oxygen atom or a carbonyl group.
R^{b12} includes the same group as R^{b1} in the formula (B1).

The compounds represented by the formula (b8) include the following compounds.

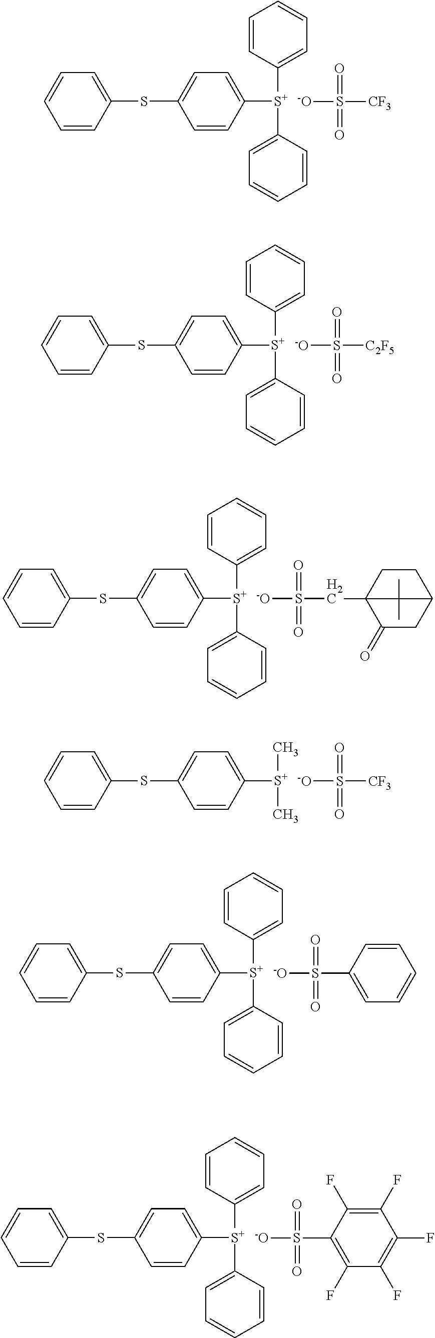

The compounds represented by the formula (b9) include the following compounds.

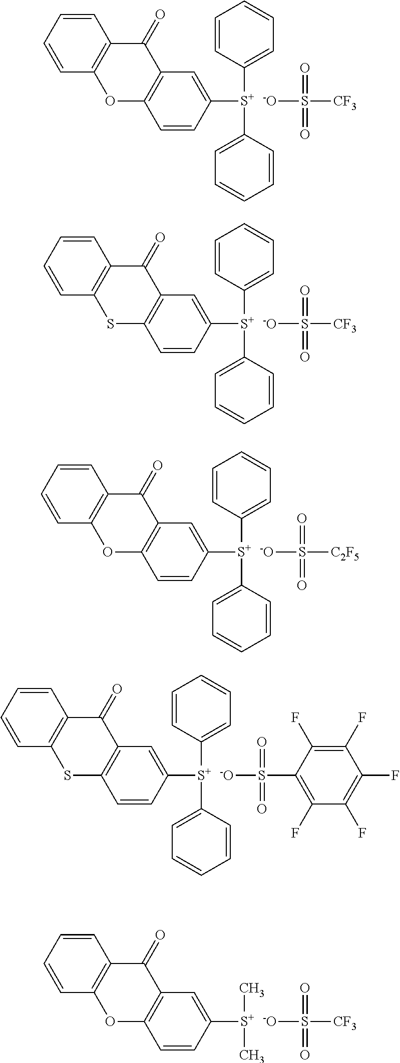

The content rate of the total of the acid generator (B) in the negative resist composition of the present invention is, with respect to 100 parts by mass of the resin, preferably 0.1 parts by mass or higher and 40 parts by mass or lower, more preferably 0.5 parts by mass or higher and 30 parts by mass or lower, still more preferably 1 part by mass or higher and 20 parts by mass or lower and further still more preferably 1 part by mass or higher and 5 parts by mass or lower.

The content of the at least two acid generators having a group represented by the formula (B1) (at least one thereof is a compound represented by the formula (b1)), contained in the acid generator (B) to be used in the present invention, is usually 30 to 100% by mass, and preferably 40 to 100% by mass, more preferably 50 to 100% by mass and especially preferably 60 to 100% by mass.

In the acid generator (B) to be used in the present invention, the content of the compound represented by the formula (b1), contained in the at least two acid generators having a group represented by the formula (B1), is usually 20 to 100% by mass, and preferably 30 to 100% by mass, more preferably 40 to 100% by mass and especially preferably 50 to 100% by mass.

### <Crosslinking Agent (E)>

The crosslinking agent (E) is a compound which is bound with the resin (A1) under the action of an acid generated by decomposition of the acid generator (B) by light irradiation (exposure). The being bound with the resin forms a crosslinking structure.

The crosslinking agent includes melamine-based ones, urea-based ones, alkylene urea-based ones, and glycoluril-based ones.

The melamine-based crosslinking agents include compounds represented by the formula (e1).

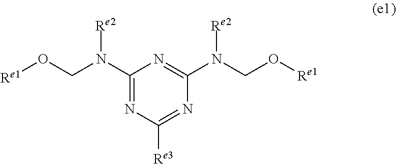

In the formula (e1),
R^{e1} each independently denote a hydrogen atom or a hydrocarbon group having 1 to 6 carbon atoms;
R^{e2} each independently denote a hydrogen atom, a hydrocarbon group having 1 to 6 carbon atoms, or —CH₂—O—R^{e1}; and
R^{e3} denotes a hydrogen atom, a hydrocarbon group having 1 to 6 carbon atoms, or a group represented by the formula (e1-1).

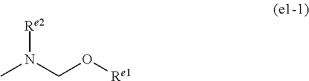

In the formula (e1-1),
R^{e1} and R^{e2} denote the same groups as in the formula (e1).

Specific examples of the melamine-based crosslinking agents include N,N,N,N,N,N-hexakis(methoxymethyl)melamine, N,N,N,N,N,N-hexakis(ethoxymethyl)melamine, N,N,N,N,N,N-hexakis(propoxymethyl)melamine, N,N,N,N,N,N-hexakis(isopropoxymethyl)melamine, N,N,N,N,N,N-hexakis(butoxymethyl)melamine, N,N,N,N,N,N-hexakis(t-butoxymethyl)melamine, N,N,N,N,N,N-hexakis(cyclohexyloxymethyl)melamine, N,N,N,N,N,N-hexakis(cyclopentyloxymethyl)melamine, N,N,N,N,N,N-hexakis(adamantyloxymethyl)melamine, N,N,N,N,N,N-hexakis(norbornyloxymethyl)melamine, N,N,N,N-tetrakis(methoxymethyl)acetoguanamine, N,N,N,N-tetrakis (ethoxymethyl)acetoguanamine, N,N,N,N-tetrakis (propoxymethyl)acetoguanamine, N,N,N,N-tetrakis (isopropoxymethyl)acetoguanamine, N,N,N,N-tetrakis (butoxymethyl)acetoguanamine, N,N,N,N-tetrakis (t-butoxymethyl)acetoguanamine, N,N,N,N-tetrakis(methoxymethyl)benzoguanamine, N,N,N,N-tetrakis (ethoxymethyl)benzoguanamine, N,N,N,N-tetrakis (propoxymethyl)benzoguanamine, N,N,N,N-tetrakis (isopropoxymethyl)benzoguanamine, N,N,N,N-tetrakis (butoxymethyl)benzoguanamine, and N,N,N,N-tetrakis (t-butoxymethyl)benzoguanamine.

The urea-based crosslinking agents include compounds represented by the formula (e2).

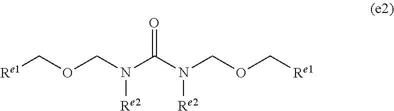

In the formula (e2),
R^{e1} and R^{e2} denote the same groups as in the formula (e1).

Specific examples of the urea-based crosslinking agents include N,N-di(methoxymethyl) urea, N,N-di(ethoxymethyl) urea, N,N-di(propoxymethyl) urea, N,N-di(isopropoxymethyl) urea, N,N-di(butoxymethyl) urea, N,N-di(t-butoxymethyl) urea, N,N-di(cyclohexyloxymethyl) urea, N,N-di(cyclopentyloxymethyl) urea, N,N-di(adamantyloxymethyl) urea, and N,N-di(norbornyloxymethyl) urea.

The alkylene urea-based crosslinking agents include compounds represented by the formula (e3).

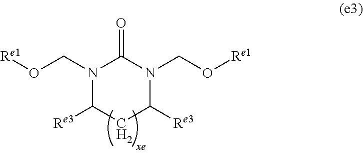

In the formula (e3),
R^{e1} denotes the same group as in the formula (e1);
R^{e3} each independently denote a hydrogen atom, a hydroxy group, a hydrocarbon group having 1 to 6 carbon atoms or an alkoxy group having 1 to 6 carbon atoms; and
xe denotes an integer of 0 to 2.

Specific examples of the alkylene urea-based crosslinking agents include N,N-di(methoxymethyl)-4,5-di(methoxymethyl)ethylene urea, N,N-di(ethoxymethyl)-4,5-di(ethoxymethyl)ethylene urea, N,N-di(propoxymethyl)-4,5-di(propoxymethyl)ethylene urea, N,N-di(isopropoxymethyl)-4,5-di(isopropoxymethyl)ethylene urea, N,N-di(butoxymethyl)-4,5-di(butoxymethyl)ethylene urea, N,N-di(t-butoxymethyl)-4,5-di(t-butoxymethyl)ethylene urea, N,N-di(cyclohexyloxymethyl)-4,5-di(cyclohexyloxymethyl)ethylene urea, N,N-di(cyclopentyloxymethyl)-4,5-di(cyclopentyloxymethyl)ethylene urea, N,N-di(adamantyloxymethyl)-4,5-di(adamantyloxymethyl)ethylene urea, and N,N-di(norbornyloxymethyl)-4,5-di(norbornyloxymethyl)ethylene urea.

The glycoluril-based crosslinking agents include the formula (e4).

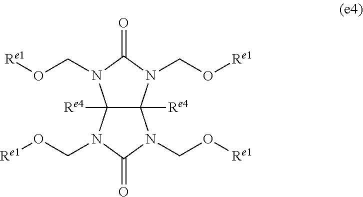

In the formula (e4),
R^{e1} denotes the same group as in the formula (e1); and
R^{e4} each independently denote a hydrogen atom, a hydroxy group, a hydrocarbon group having 1 to 6 carbon atoms, or an alkoxy group having 1 to 6 carbon atoms.

Specific examples of the glycoluril-based crosslinking agents include N,N,N,N-tetra(methoxymethyl)glycoluril, N,N,N,N-tetra(ethoxymethyl)glycoluril, N,N,N,N-tetra(propoxymethyl)glycoluril, N,N,N,N-tetra(isopropoxymethyl)glycoluril, N,N,N,N-tetra(butoxymethyl)glycoluril, N,N,N,N-tetra(t-butoxymethyl)glycoluril, N,N,N,N-tetra(cyclohexyloxymethyl)glycoluril, N,N,N,N-tetra(cyclopentyloxymethyl)glycoluril, N,N,N,N-tetra(adamantyloxymethyl)glycoluril, and N,N,N,N-tetra(norbornyloxymethyl)glycoluril.

The crosslinking agent (E) is, among in the above, preferably a melamine-based one or a glycoluril-based one. The crosslinking agents (E) may be used singly, or in combination of two or more.

In the negative resist composition of the present invention, the content of the crosslinking agent (E) is, with respect to 100 parts by mass of the resin, preferably 1 to 50 parts by mass, more preferably 2 to 40 parts by mass and still more preferably 3 to 30 parts by mass.

### <Solvent (D)>

The content rate of the solvent (D) is, in the negative resist composition, usually 45% by mass or higher, preferably 50% by mass or higher and more preferably 55% by mass or higher, and usually 99.9% by mass or lower, preferably 99% by mass or lower and more preferably 90% by mass or lower. The content rate of the solvent (E) can be measured, for example, by a well-known analysis means such as liquid chromatography or gas chromatography.

Examples of the solvent (D) include glycol ether esters such as ethyl cellosolve acetate, methyl cellosolve acetate and propylene glycol monomethyl ether acetate; glycol ethers such as propylene glycol monomethyl ether; esters such as ethyl lactate, butyl acetate, amyl acetate and ethyl pyruvate; ketones such as acetone, methyl isobutyl ketone, 2-heptanone and cyclohexanone; and cyclic esters such as γ-butyrolactone.

The solvents (D) may be contained singly, or in combination of two or more.

### <Quencher (C)>

The negative resist composition of the present invention may contain a quencher (hereinafter, referred to as a “quencher (C)” in some cases).

The quencher (C) is a compound which has an action of capturing an acid generated from the acid generator by exposure. The quencher (C) includes basic nitrogen-containing organic compounds. The basic nitrogen-containing organic compounds include amines and ammonium salts. The amines include aliphatic amines (including primary amines, secondary amines and tertiary amines), and aromatic amines.

Examples of the amines include compounds represented by the formula (C1) and the formula (C2).

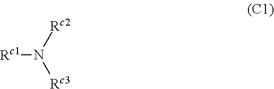

In the formula (C1), R^{C1}, R^{C2} and R^{C3} each independently denote a hydrogen atom, an alkyl group having 1 to 6 carbon atoms, an alicyclic hydrocarbon group having 3 to 10 carbon atoms, or an aromatic hydrocarbon group having 6 to 10 carbon atoms; and the alkyl group having 1 to 6 carbon atoms and the alicyclic hydrocarbon group having 3 to 10 carbon atoms optionally have at least one selected from the group consisting of a hydroxy group, an amino group and an alkoxy group having 1 to 6 carbon atoms, and the aromatic hydrocarbon group having 6 to 10 carbon atoms optionally has at least one selected from the group consisting of alkyl groups having 1 to 6 carbon atoms, alkoxy groups having 1 to 6 carbon atoms, and alicyclic hydrocarbon groups having 3 to 10 carbon atoms.

Examples of the compounds represented by the formula (C1) include 1-naphthylamine, 2-naphthylamine, aniline, diisopropylaniline, 2-, 3- or 4-methylaniline, 4-nitroaniline, N-methylaniline, N,N-dimethylaniline, diphenylamine, hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, dibutylmethylamine, methyldipentylamine, dihexylmethylamine, dicyclohexylmethylamine, diheptylmethylamine, methyldioctylamine, methyldinonylamine, didecylmethylamine, ethyldibutylamine, ethyldipentylamine, ethyldihexylamine, ethyldiheptylamine, ethyldioctylamine, ethyldinonylamine, ethyldidecylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane, and 4,4′-diamino-3,3′-diethyldiphenylmethane. Preferably, diisopropylaniline is included, and especially preferably, 2,6-diisopropylaniline is included.

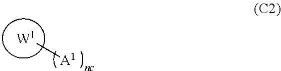

In the formula (C2),
the ring W¹ denotes a hetero ring containing a nitrogen atom(s) as atoms constituting the ring, or a benzene ring having a substituted or non-substituted amino group; and the hetero ring and the benzene ring optionally have at least one selected from the group consisting of a hydroxy group and an alkyl group having 1 to 4 carbon atoms.
A¹ denote a phenyl group or a naphthyl group.
nc denotes 2 or 3, and the plurality of A¹ may be identical or different.

The substituted or non-substituted amino group is denoted as —N(R⁴) (R⁵), and R⁴ and R⁵ each independently denote a hydrogen atom, an acyclic hydrocarbon group having 1 to 10 carbon atoms, an alicyclic hydrocarbon group having 3 to 10 carbon atoms or an aromatic hydrocarbon group having 6 to 14 carbon atoms.

Examples of the acyclic hydrocarbon group having 1 to 10 carbon atoms include alkyl groups having 1 to 10 carbon atoms, such as a methyl group, an ethyl group, a propyl group, a butyl group, a pentyl group, a hexyl group, a heptyl group and an octyl group.

Examples of the alicyclic hydrocarbon group having 3 to 10 carbon atoms include monocyclic alicyclic hydrocarbon groups such as a cyclopentyl group, a cyclohexyl group, a cycloheptyl group, and a cyclooctyl group; and polycyclic alicyclic hydrocarbon groups such as a decahydronaphthyl group, an adamantyl group and a norbornyl group.

Examples of the aromatic hydrocarbon group having 6 to 14 carbon atoms include aryl groups such as a phenyl group, a naphthyl group, an anthryl group, a biphenyl group and a phenanthryl group. The aromatic hydrocarbon groups optionally further have a substituent, and examples of the substituent include aryloxy groups having 6 to 10 carbon atoms.

The hetero ring containing a nitrogen atom(s) as atoms constituting the ring may be an aromatic ring or a non-aromatic ring, and may have another heteroatom (for example, an oxygen atom or a sulfur atom) together with the nitrogen atom(s). The number of nitrogen atoms the hetero ring has is, for example, 1 to 3. Examples of the hetero ring include rings represented by one of the formula (Y13) to the formula (Y28). One of hydrogen atoms contained in the ring is eliminated and the site becomes a bond with A¹.

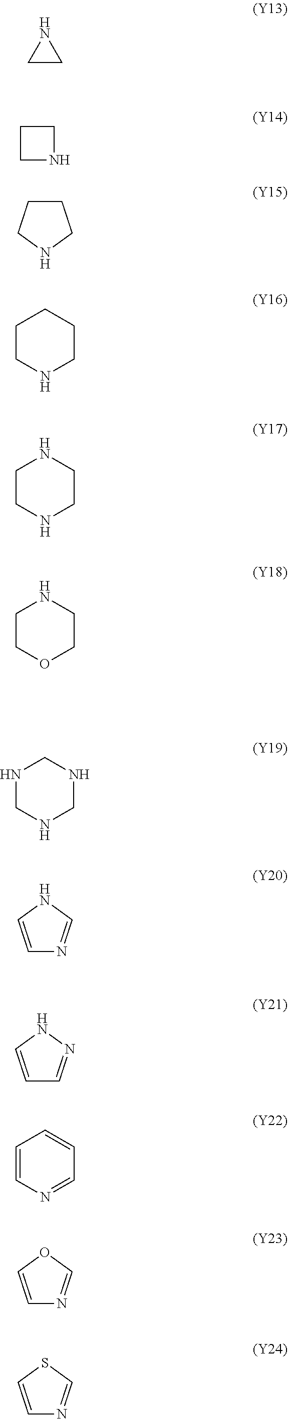

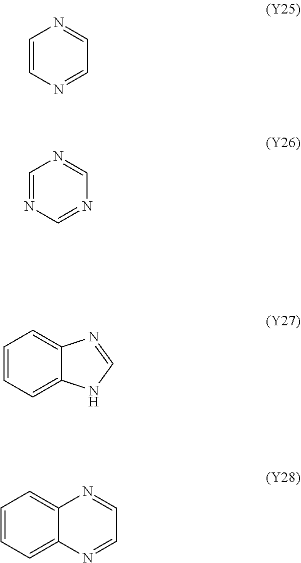 [SMILES: c1cnccn1 ; c1ncncn1 ; c1ccc2[nH]cnc2c1 ; c1ccc2nccnc2c1]

The ring W¹ is preferably a hetero ring containing a nitrogen atom(s) as atoms constituting the ring, more preferably a 5-membered or 6-membered aromatic hetero ring containing a nitrogen atom(s) as atoms constituting the ring, and still more preferably a ring represented by one of the formula (Y20) to the formula (Y25).

Examples of the compounds represented by the formula (C2) include compounds represented by one of the formula (C2-1) to the formula (C2-11). Preferable are compounds represented by one of the formula (C2-2) to the formula (C2-8).

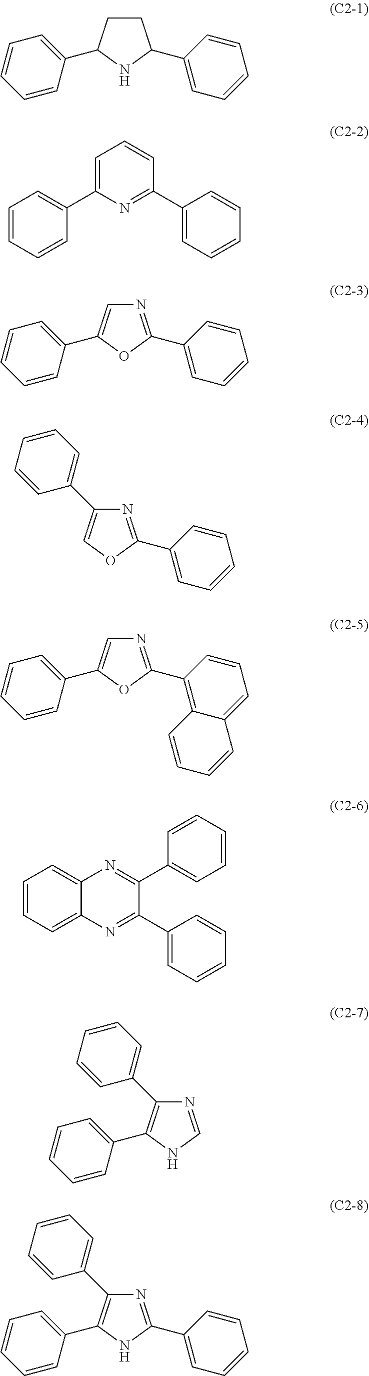

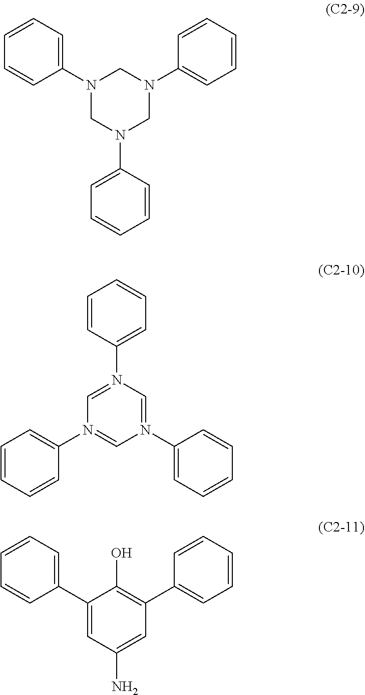

The content rate of the quencher (C) is, in the solid content of the negative resist composition, preferably 0.0001 to 5% by mass, more preferably 0.0001 to 4% by mass, still more preferably 0.001 to 3% by mass, further still more preferably 0.01 to 1.0% by mass and even further still more preferably 0.1 to 0.7% by mass.

### <Other Components>

The negative resist composition of the present invention, as required, may contain components (hereinafter, referred to as “other components (F)” in some cases) other than the above-mentioned components. The other components (F) are not especially limited, and additives well-known in the resist field can be utilized, such as sensitizers, dissolution inhibitors, surfactants, stabilizers, dyes and adhesion improvers.

In the case of using the other components (F), the contents thereof are suitably selected depending on the types of the other components (F).

### 2. Preparation of the Negative Resist Composition

The negative resist composition of the present invention can be prepared by mixing the resin (A1), the crosslinking agent (E) and the acid generator (B), and as required, resins other than the resin (A1), the quencher (C), the solvent (D) and the other components (F). The mixing order is optional and is not especially limited. The temperature in the mixing includes 10 to 40° C. and can suitably be selected depending on the types of the resins and the like, the solubility of the resins and the like to the solvent (D), and the like. The mixing time can suitably be selected from 0.5 to 24 hours depending on the mixing temperature. Then, mixing means is not also especially limited and agitating mixing or the like can be used.

It is preferable that after the each component is mixed, the mixture is filtrated by using a filter of about 0.003 to 50 μm in pore size.

### 3. Method of Producing a Resist Pattern

The method for producing a resist pattern of the present invention comprises:
(1) a step of coating a substrate with the negative resist composition of the present invention;
(2) a step of drying the negative resist composition after the coating to form a composition layer;
(3) a step of exposing the composition layer; and
(4) a step of heating and developing the composition layer after the exposure.

The coating of a substrate with the negative resist composition can be carried out by an apparatus usually used, such as a spin coater. The substrate includes inorganic substrates such as silicon wafers, and semiconductor elements (for example, transistors and diodes) may previously be formed on the substrate.

By drying the composition after the coating, the solvent is removed to form the composition layer. The drying is carried out, for example, by evaporating (so-called prebaking) the solvent by using a heating apparatus such as a hot plate, or carried out by using a vacuum apparatus. The heating temperature is preferably 50 to 200° C.; and the heating time is preferably 30 to 600 sec. Then, the pressure in the vacuum drying is preferably about 1 to 1.0×10⁵ Pa.

The film thickness of the composition obtained by the drying is preferably 1 to 50 μm and more preferably 1.5 to 30 μm.

The obtained composition layer is exposed usually by using an aligner. Various exposure light sources can be used, including those emitting light of a wavelength of 345 to 436 nm (g line (wavelength: 436 nm), h line (wavelength: 405 nm), i line (wavelength: 365 nm)), those emitting laser light in the ultraviolet region such as a KrF exima laser (wavelength: 248 nm), an ArF exima laser (wavelength: 193 nm) and a F₂ exima laser (wavelength: 157 nm), those emitting high-frequency laser light in the deep ultraviolet region or the vacuum ultraviolet region by converting the wavelength of laser light from solid laser light sources (YAG, semiconductor lasers or the like), and those emitting electron beams, or extreme ultraviolet light (EUV).

Then, in the present description, the irradiation with these radioactive rays is generically referred to as “exposure” in some cases. The exposure is carried out usually through masks corresponding to required patterns. In the case where the exposure light source is electron beams, the exposure may be carried out by direct drawing without using masks.

The composition layer after the exposure may be subjected to a heat treatment (so-called post-exposure bake) in order to promote the crosslinking reaction between the resin and the crosslinking agent. The heating temperature is usually about 50 to 200° C. and preferably about 70 to 150° C. The heating time is usually 40 to 400 sec and preferably 50 to 350 sec.

The composition layer after the heating is developed usually by using a developer and utilizing a developing solution. The development method includes a dipping method, a paddle method, a spray method and a dynamic dispense method. The developing temperature is preferably, for example, 5 to 60° C.; and the developing time is preferably, for example, 5 to 600 sec.

The negative resist composition of the present invention uses an alkali developing solution as the developing solution. The alkali developing solution suffices as long as being various types of alkali developing solutions used in this field. Examples thereof include aqueous solutions of tetramethylammonium hydroxide and (2-hydroxyethyl)trimethylammonium hydroxide (common name: choline). The alkali developing solution may contain a surfactant.

After the development, it is preferable that the resist pattern is cleaned with ultrapure water, and then, the substrate and water remaining on the pattern are removed.

After the cleaning, it is preferable that the substrate and the rinsing liquid remaining on the pattern are removed.

By exposing a resist obtained by using the negative resist composition of the present invention, the resist pattern having a high-precision shape can be formed.

### 4. Applications

The negative resist composition of the present invention is useful for production of thick resist films.

It is useful, for example, for production of resist films of 1 to 50 μm in film thickness.

### EXAMPLES

The present invention will be described more specifically by way of Examples. In the Examples, “%” and “parts” indicating a content or an amount used are in terms of mass unless otherwise specified.

The weight-average molecular weight is a value determined by gel permeation chromatography under the following conditions.
Apparatus: HLC-8320GPC type (manufactured by Tosoh Corp.)
Columns: TSKgel Multipore H_{XL}-M×3+Guard Column (manufactured by Tosoh Corp.), Eluate: tetrahydrofuran
Flow rate: 1.0 mL/min
Detector: RI detector
Column temperature: 40° C.
Injection volume: 100 μl
Molecular weight standard: standard polystyrene (manufactured by Tosoh Corp.)

### Synthesis Example 1 [Synthesis of Resin (A2)-1]

To a four-necked flak equipped with a stirrer, a reflux cooling tube and a thermometer, 413.5 parts of 2,5-xylenol, 103.4 parts of salicylaldehyde, 20.1 parts of p-toluenesulfonic acid, and 826.9 parts of methanol were added, and the resultant was heated up to reflux and the temperature was held for 4 hours. After cooling, 1, 320 parts of methyl isobutyl ketone was added and 1,075 parts of the solvent was distilled away at the atmospheric pressure. Thereto, 762.7 parts of m-cresol and 29.0 parts of 2-tert-butyl-5-methylphenol were added, and heated up to 65° C.; and 678 parts of 37% formalin was added dropwise over 1.5 hours under such a temperature control that the temperature became 87° C. at the end of the dropping. A resultant mixture was held at 87° C. for 10 hours; and 1, 115 parts of methyl isobutyl ketone was added; and the resultant was separated three times with ion-exchange water to be cleaned. 500 parts of methyl isobutyl ketone was added to a resultant mixture, and the resultant was subjected to vacuum concentration until the total amount became 3, 435 parts. 3,796 parts of methyl isobutyl ketone and 4,990 parts of n-heptane were added to a resultant mixture, and heated to 60° C. and stirred for 1 hour. Thereafter, liquid separation was carried out; and a lower layer containing a resin was taken out, diluted with 3,500 parts of propylene glycol monomethyl ether acetate and concentrated to thereby obtain 1, 690 parts (solid content: 43%) of a propylene glycol monomethyl ether acetate solution of a resin (A2)-1. The weight-average molecular weight of the novolac resin (A2)-1 was 7×10³.

### <Preparation of Negative Resist Compositions>

Mixtures obtained by mixing and dissolving each component indicated in Table 1 were filtered with a fluororesin-made filter of 0.5 μm in pore size to thereby prepare negative resist compositions.

TABLE 1

| Negative resist | Resin (A1) and | Acid | Crosslinking | | |
|---|---|---|---|---|---|
| composition | Resin (A2) | generator (B) | agent (E) | Quencher (C) | Solvent (D) |
| Composition 1 | (A1)-1 = 13.5 | (B)-1 = 0.15 | (E)-1 = 0.354 | (C)-1 = 0.046 | (D)-1 = 26 |
| | parts | parts | parts | parts | parts |
| | | (B)-2 = 0.15 | | | |
| | | parts | | | |
| Composition 2 | (A1)-1 = 8.1 | (B)-1 = 0.15 | (E)-1 = 0.354 | (C)-1 = 0.046 | (D)-1 = 26 |
| | parts | parts | parts | parts | parts |
| | (A2)-1 = 5.4 | (B)-2 = 0.15 | | | |
| | parts | parts | | | |
| Composition 3 | (A1)-1 = 8.1 | (B)-1 = 0.15 | (E)-1 = 1.000 | (C)-1 = 0.030 | (D)-1 = 26 |
| | parts | parts | parts | parts | parts |
| | (A2)-2 = 5.4 | (B)-2 = 0.15 | | | |
| | parts | parts | | | |
| Composition 4 | (A1)-1 = 8.1 | (B)-1 = 0.15 | (E)-2 = 1.246 | (C)-1 = 0.030 | (D)-1 = 26 |
| | parts | parts | parts | parts | parts |
| | (A2)-2 = 5.4 | (B)-2 = 0.15 | | | |
| | parts | parts | | | |
| Composition 5 | (A1)-1 = 8.1 | (B)-1 = 0.15 | (E)-1 = 0.354 | (C)-1 = 0.046 | (D)-1 = 26 |
| | parts | parts | parts | parts | parts |
| | (A2)-1 = 5.4 | (B)-3 = 0.15 | | | |
| | parts | parts | | | |
| Composition 6 | (A1)-1 = 8.1 | (B)-2 = 0.15 | (E)-1 = 0.354 | (C)-1 = 0.046 | (D)-1 = 26 |
| | parts | parts | parts | parts | parts |
| | (A2)-1 = 5.4 | (B)-3 = 0.15 | | | |
| | parts | parts | | | |
| Comparative | (A1)-1 = 8.1 | (B)-1 = 0.30 | (E)-1 = 0.354 | (C)-1 = 0.046 | (D)-1 = 26 |
| Composition 1 | parts | parts | parts | parts | parts |
| | (A2)-1 = 5.4 | | | | |
| | parts | | | | |
| Comparative | (A1)-1 = 8.1 | (B)-3 = 0.30 | (E)-1 = 0.354 | (C)-1 = 0.046 | (D)-1 = 26 |
| Composition 2 | parts | parts | parts | parts | parts |
| | (A2)-1 = 5.4 | | | | |
| | parts | | | | |

### <Resins>

(A1)-1: Resin (A1)-1

A resin having the following structural units, which was synthesized by a method disclosed in Japanese Patent Laid-Open No. 2001-42529.

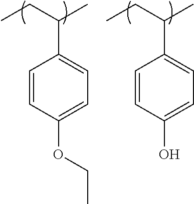

Weight-average molecular weight: 3,700

The proportion in which hydroxy groups in a poly-p-hydroxystyrlene were substituted by ethoxy groups was 20.9%.

(A2)-1: Resin (A2)-1

which was synthesized in Synthesis Example 1.

(A2)-2: Resin (A2)-2

A resin having the following structural unit, which was synthesized by a method disclosed in Japanese Patent Laid-Open No. 2001-42529.

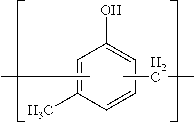

Weight-average molecular weight: 9,250

### <Acid Generators (B)>

(B)-1: N-hydroxynaphthalimido-triflate (manufactured by Heraeus Holding GmbH)

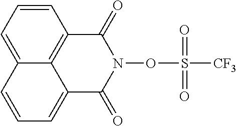 [SMILES: O=C1c2cccc3cccc(c23)C(=O)N1OS(=O)(=O)C(F)(F)F]

(B)-2: which was synthesized by a method disclosed in WO2014/084269.

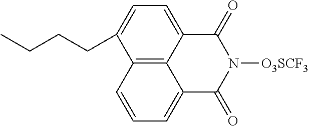

(B)-3: a compound represented by the following formula (PAG-121, manufactured by BASF AG)

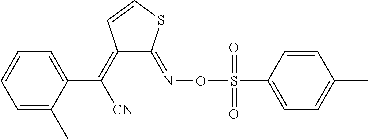 [SMILES: Cc1ccc(S(=O)(=O)O/N=C2\SC=C\C2=C(\C#N)c2ccccc2C)cc1]

### <Crosslinking Agent (E)>

(E)-1: N,N,N,N,N,N-hexakis(methoxymethyl)melamine (manufactured by Tokyo Chemical Industry Co., Ltd.)

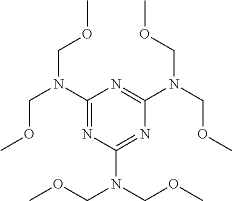

(E)-2: a compound represented by the following formula (manufactured by Heraeus Holding GmbH)

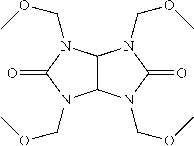

### <Quencher (C)>

(C)-1:2,4,5-triphenylimidazole (manufactured by Tokyo Chemical Industry Co., Ltd.)

### <Solvent (D)>

(D)-1: propylene glycol monomethyl ether acetate

### Examples 1 to 6 and Comparative Examples 1 and 2

### (Evaluation of i Line Exposure of the Negative Resist Compositions)

A 4-inch silicon wafer substrate treated with hexamethyldisilazane (HMDS) was spin coated with any one of the above negative resist compositions so that the film thickness after prebaking became 6 μm.

Thereafter, the resultant was prebaked at 100° C. for 180 sec on a direct hot plate to thereby form a composition layer.

Then, the composition layer formed on the wafer was exposed by using an i-line stepper (NSR-200519C, manufactured by Nikon Corp., NA=0.5) and stepwise changing the exposure amount through a mask for forming a trench pattern (trench width: 3, 2, 1 μm).

After the exposure, the resultant was subjected to post-exposure baking at 100° C. for 60 sec on a hot plate, and further to paddle development for 180 sec with an aqueous solution of 2.38% by mass tetramethylammonium hydroxide to thereby obtain a resist pattern.

The resist pattern obtained after the development was observed with a scanning electron microscope, and an exposure amount could give a 3 μm-width trench was determined as an effective sensitivity.

### <Evaluation of the Resolution>

The resist pattern obtained in the effective sensitivity evaluation was observed with a scanning electron microscope and the minimum value of the line width of the trench pattern which could be resolved was measured.

### <Evaluation of the Shape>

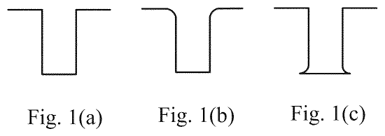

The 3-μm trench pattern obtained in the effective sensitivity evaluation was observed with a scanning electron microscope; and the case where the top shape and the bottom shape were nearly rectangular and good [(a) in FIG. 1] was evaluated as “◯”; the case where the top shape was round [(b) in FIG. 1] or the bottom shape had notches [(c) in FIG. 1], as “Δ”; and the case where the top shape was round [(b) in FIG. 1] and the bottom shape had notches [(c) in FIG. 1], as “x”. The results are shown in Table 2.

### <Evaluation of the Storage Stability>

The above negative resist composition was stored at −5° C. for 1 month and the state thereof was visually observed. The case where no solids precipitated was evaluated as “◯”; and the case where solids precipitated, as “x”.

TABLE 2

| | Negative resist | Storage | Resolution | |
|---|---|---|---|---|
| | composition | stability | (μm) | Shape |
| Example 1 | Composition 1 | ∘ | 2 | Δ |
| Example 2 | Composition 2 | ∘ | 2 | ∘ |
| Example 3 | Composition 3 | ∘ | 2 | ∘ |
| Example 4 | Composition 4 | ∘ | 2 | ∘ |
| Example 5 | Composition 5 | ∘ | 2 | ∘ |
| Example 6 | Composition 6 | ∘ | 2 | ∘ |
| Comparative | Comparative | x | 3 | ∘ |
| Example 1 | Composition 1 | | | |
| Comparative | Comparative | — | not resolved | — |
| Example 2 | Composition 2 | | | |

Examples 1 to 6 gave good storage stability. Furthermore, Examples 1 to 6 also gave good resolution and good shapes. By contrast, in Comparative Example 1, since the acid generator included only one ((B)-1), the storage stability was poor. In Comparative Example 2, since the acid generator included only one ((B)-3), the resist pattern was not resolved.

### INDUSTRIAL APPLICABILITY

The negative resist composition of the present invention has good storage stability and is useful for microfabrication of semiconductors.

1. A negative resist composition, comprising: a resin (A1); an acid generator (B); and a crosslinking agent (E),
wherein the resin (A1) comprises a structural unit represented by the formula (a2-1) and a structural unit represented by the formula (a2-4); and
the acid generator (B) comprises at least two acid generators each having a group represented by the formula (B1), and at least one thereof is a compound represented by the formula (b1): 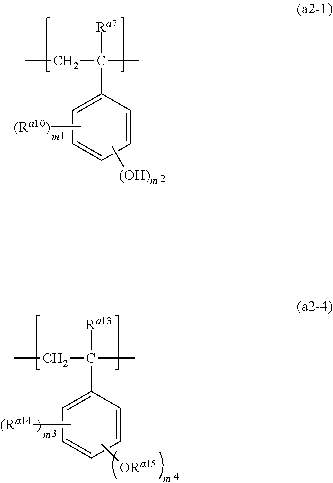
in the formula (a2-1) and the formula (a2-4),
R^{a7} and R^{a13} each independently denote a hydrogen atom or a methyl group;
R^{a10} and R^{a14} each independently denote an alkyl group having 1 to 6 carbon atoms;
R^{a15} denotes a hydrocarbon group having 1 to 12 carbon atoms;
m¹ denotes an integer of 0 to 4, and when m¹ is 2 or more, the plurality of R^{a10} are identical with or different from each other;
m² denotes an integer of 1 to 4;
provided a total of m¹ and m² is 5 or less;
m³ denotes an integer of 0 to 4, and when m³ is 2 or more, the plurality of R^{a14} are identical with or different from each other;
m⁴ denotes an integer of 1 to 4, and when m⁴ is 2 or more, the plurality of R^{a15} are identical with or different from each other; and
provided a total of m³ and m⁴ is 5 or less; 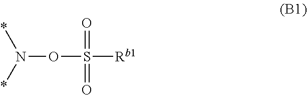
in the formula (B1),
R^{b1} denotes a hydrocarbon group having 1 to 18 carbon atoms and optionally having a fluorine atom(s); and
a methylene group contained in the hydrocarbon group is optionally substituted by an oxygen atom or a carbonyl group; and 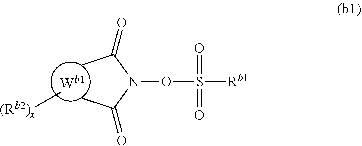
in the formula (b1),
R^{b1} denotes the same meaning as described above;
R^{b2} denotes a hydrocarbon group having 1 to 8 carbon atoms, an alkoxy group having 1 to 8 carbon atoms or a thioalkyl group having 1 to 8 carbon atoms;
the ring W^{b1} denotes an aromatic hydrocarbon ring having 6 to 14 carbon atoms or an aromatic hetero ring having 6 to 14 carbon atoms; and
x denotes an integer of 0 to 6, and in the case where x is 2 or more, the plurality of R^{b2} are identical or different.

2. The negative resist composition according to claim 1,
wherein the acid generator (B) comprises
(i) a combination of at least two selected from compounds represented by the formula (b1); or
(ii) a combination of at least one selected from compounds represented by the formula (b1) with at least one selected from compounds represented by the formula (b2) and compounds represented by the formula (b3): 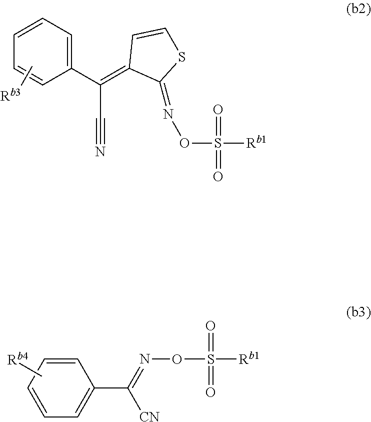
in the formula (b2) and the formula (b3),
R^{b1} denotes the same meaning as described above; and
R^{b3} and R^{b4} each independently denote a hydrocarbon group having 1 to 8 carbon atoms, an alkoxy group having 1 to 8 carbon atoms or a thioalkyl group having 1 to 8 carbon atoms.

3. The negative resist composition according to claim 1, wherein at least one contained in the acid generator (B), selected from compounds represented by the formula (b1) is a compound wherein x is 1.

4. The negative resist composition according to claim 1, further comprising a novolac resin.

5. The negative resist composition according to claim 1, further comprising a quencher (C).

6. The negative resist composition according to claim 1, wherein the crosslinking agent (E) is a melamine-based crosslinking agent or a glycoluril-based crosslinking agent.

7. A method for producing a resist pattern, comprising:
(1) a step of coating a substrate with the negative resist composition according to claim 1;
(2) a step of drying the composition after the coating to form a composition layer;
(3) a step of exposing the composition layer; and
(4) a step of heating and developing the composition layer after the exposure.
